(19) United States
(12) Patent Application Publication
(10) Pub. No.: US 2026/0147058 A1
(43) Pub. Date: May 28, 2026

(54) SECONDARY BATTERY SYSTEM

(71) Applicant: TOYOTA JIDOSHA KABUSHIKI KAISHA, Toyota-shi (JP)

(72) Inventor: Yukiyoshi UENO, Toyota-shi (JP)

(73) Assignee: TOYOTA JIDOSHA KABUSHIKI KAISHA, Toyota-shi (JP)

(21) Appl. No.: 19/282,412

(22) Filed: Jul. 28, 2025

(30) Foreign Application Priority Data
Nov. 26, 2024 (JP) 2024-205499

(51) Int. Cl. G01R 31/392; G01R 31/374; G01R 31/389; H01M 10/42

(52) U.S. Cl. CPC G01R 31/392; G01R 31/374; G01R 31/389; H01M 10/4285

(57) ABSTRACT

A secondary battery system that estimates deterioration of a secondary battery includes: an acquisition unit configured to acquire an internal resistance, an internal pressure, and a temperature of a battery cell; a first estimation unit configured to estimate the deterioration of the secondary battery based on the internal resistance when the temperature is equal to or lower than a first threshold value; a second estimation unit configured to estimate the deterioration of the secondary battery based on the internal pressure when the temperature is equal to or higher than a second threshold value; a third estimation unit configured to estimate the deterioration of the secondary battery based on both the internal resistance and the internal pressure when the temperature is higher than the first threshold value and lower than the second threshold value.

### CROSS-REFERENCE TO RELATED APPLICATION

This application claims priority to Japanese Patent Application No. 2024-205499 filed on Nov. 26, 2024. The disclosure of the above-identified application, including the specification, drawings, and claims, is incorporated by reference herein in its entirety.

### BACKGROUND

### 1. Technical Field

The present disclosure relates to a secondary battery system capable of estimating deterioration of a secondary battery.

### 2. Description of Related Art

Japanese Unexamined Patent Application Publication No. 2017-150926 (JP 2017-150926 A) discloses a deterioration determination device that determines deterioration of a secondary battery based on an internal resistance calculated from a voltage value and a current value of a battery cell.

### SUMMARY

As in the technique described in JP 2017-150926 A, in a method of estimating the deterioration of the secondary battery based on the internal resistance calculated from the voltage value and the current value of the battery cell, the absolute value of the internal resistance becomes smaller as the temperature of the battery cell becomes higher. Therefore, distinguishing the difference between before and after the deterioration may be difficult. Therefore, there is room for further study on the method of estimating the deterioration of the secondary battery in order to improve the accuracy.

The present disclosure has been made in view of the above problems, and an object of the present disclosure is to provide a secondary battery system that improves the accuracy of estimating deterioration of a secondary battery.

In order to solve the above problem, an aspect of the present disclosure relates to a secondary battery system that estimates deterioration of a secondary battery.
The secondary battery system includes
an acquisition unit configured to acquire an internal resistance, an internal pressure, and a temperature of a battery cell,
a first estimation unit configured to estimate the deterioration of the secondary battery based on the internal resistance when the temperature is equal to or lower than a first threshold value,
a second estimation unit configured to estimate the deterioration of the secondary battery based on the internal pressure when the temperature is equal to or higher than a second threshold value, and
a third estimation unit configured to estimate the deterioration of the secondary battery based on both the internal resistance and the internal pressure when the temperature is higher than the first threshold value and lower than the second threshold value.

With the secondary battery system according to the present disclosure, the deterioration estimation of the secondary battery is performed using an optimum method depending on the temperature of the battery cell, so that the accuracy of the deterioration estimation of the secondary battery can be improved.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic configuration diagram of a secondary battery system and a secondary battery according to an embodiment of the present disclosure; and

FIG. 2 is a processing flowchart of deterioration estimation control of a secondary battery that is executed by the secondary battery system.

### DETAILED DESCRIPTION OF EMBODIMENTS

The secondary battery system of the present disclosure is configured to construct a deterioration estimation (detection) system with higher accuracy by measuring an increase in internal pressure due to gas generated by deterioration of a power storage device by measuring a cell pressure in addition to the deterioration estimation (detection) by measuring a capacity and a resistance using a cell voltage and current sensor in the related art and combining both results.
Hereinafter, an embodiment of the present disclosure will be described in detail with reference to the drawings.

### Embodiment

### Configuration

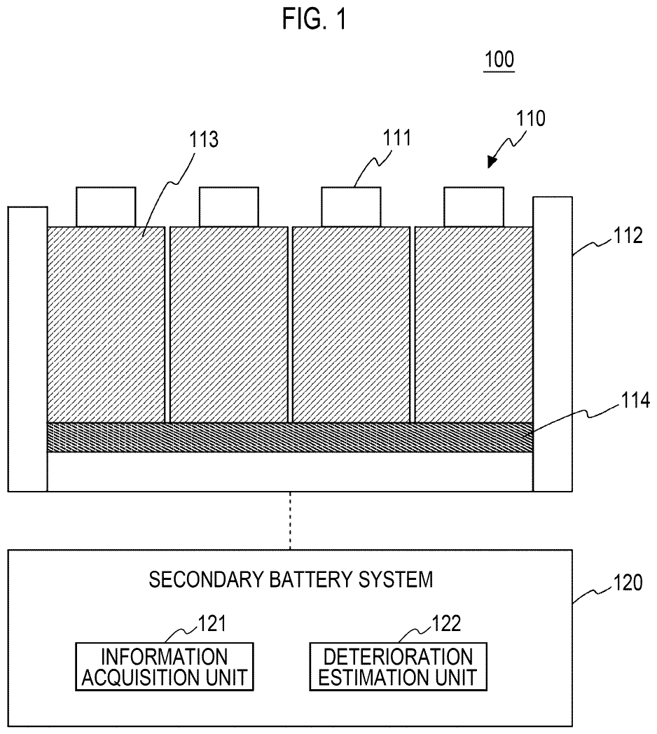

FIG. 1 is a diagram showing a schematic configuration of a power supply system 100 including a secondary battery system 120 according to an embodiment of the present disclosure. The power supply system 100 illustrated in FIG. 1 includes a secondary battery 110 and a secondary battery system 120. The power supply system 100 is mounted on, for example, a vehicle.

The secondary battery 110 is a power storage device configured to be chargeable and dischargeable, such as a lithium ion battery. When the secondary battery 110 is mounted on a vehicle, the secondary battery 110 can be used as a redundant sub-battery for backing up a main battery that supplies electric power to an in-vehicle load, for example. The secondary battery 110 includes a plurality of battery cells 111, an exterior case 112, a voltage/current/temperature sensor 113, and a pressure sensor 114.

The battery cells 111 are typically configured as a stack in which lithium ion battery cells are connected in series and/or in parallel. In FIG. 1, an example of a battery stack in which four battery cells 111 are connected in series is shown, but the number of battery cells 111 and the connection configuration are not limited thereto.

The exterior case 112 is a housing for housing the battery cells 111 that are a battery stack. The exterior case 112 is a substantially box-shaped member formed of a material having an insulating property, such as resin.

The voltage/current/temperature sensor 113 is a device that detects the voltage, the current, and the temperature of the battery cell 111. The values of the voltage, the current, and the temperature detected by the voltage/current/temperature sensor 113 are output to the secondary battery system 120.

The pressure sensor 114 is a device that detects the internal pressure of the battery cell 111. The pressure sensor 114 measures a change in a cell internal pressure due to gas generated as the deterioration of the battery cell 111 progresses. It is generally known that gas is generated by a chemical reaction as the battery deteriorates. The internal pressure of the battery cell 111, which is a closed space, increases with the amount of gas generated, and the pressure sensor 114 detects the change. The internal pressure p increases as the temperature T increases in accordance with the general state equation “pV=nRT”, so that a difference before and after the deterioration can be easily detected. As the measurement method, a method of restraining the battery cell 111 and measuring a reaction force due to the expansion of the cell case by the cell internal pressure as an internal pressure can be exemplified. The battery cell 111 is restrained at a certain pressure by a restraining member, which can be implemented in the typical cell stacking.

The secondary battery system 120 is a system for controlling and managing the secondary battery 110. The secondary battery system 120 of the present embodiment estimates the deterioration of the secondary battery 110 in particular. The secondary battery system 120 includes an information acquisition unit 121 and a deterioration estimation unit 122.

The information acquisition unit 121 acquires the voltage, the current, and the temperature of the battery cell 111 from the voltage/current/temperature sensor 113, and the internal pressure of the battery cell 111 from the pressure sensor 114, as the state of the secondary battery 110.

The deterioration estimation unit 122 estimates (or determines) the deterioration of the secondary battery 110 based on the state of the secondary battery 110 acquired by the information acquisition unit 121. In the present embodiment, two methods, that is, a deterioration estimation method based on the internal resistance due to the discharge of the battery cell 111 and a deterioration estimation method based on the internal pressure measured by pressure measurement of the battery cell 111, are appropriately used to estimate the deterioration of the secondary battery 110. Details of the deterioration estimation control of the secondary battery 110 performed by the deterioration estimation unit 122 will be described below.

A part or all of the secondary battery system 120 is configured as an electronic control unit (ECU). The ECU typically includes a processor, a memory, an input and output interface, and the like, such as a microcomputer. The electronic control unit can realize a part or all of the functions of the information acquisition unit 121 and the deterioration estimation unit 122 described above by the processor reading and executing the program stored in the memory.

### Control

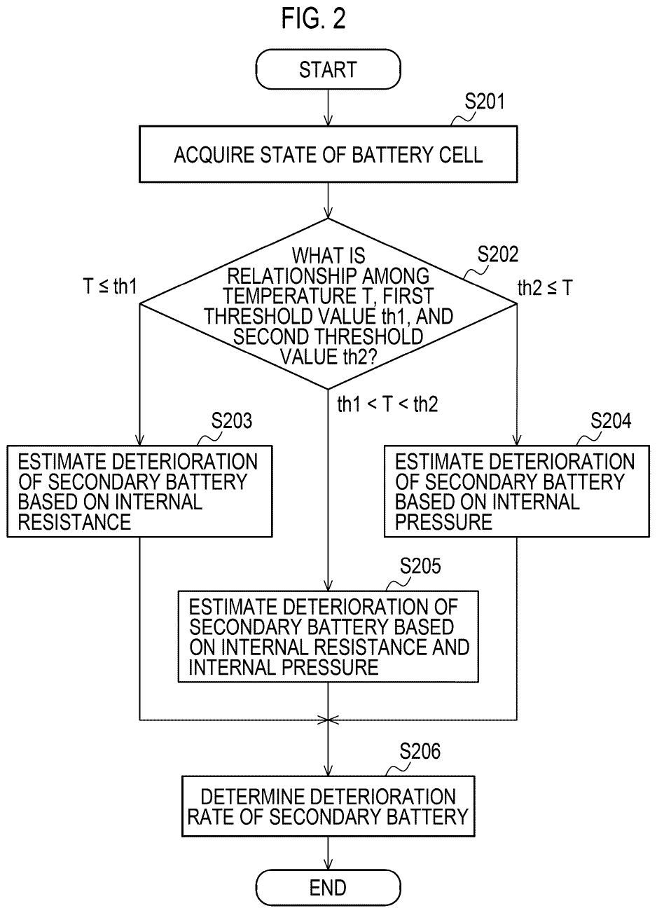

Next, control that is executed by the secondary battery system 120 according to an embodiment of the present disclosure will be described with further reference to FIG. 2. FIG. 2 is a flowchart illustrating a procedure of the deterioration estimation control of the secondary battery 110 executed by the information acquisition unit 121 and the deterioration estimation unit 122 of the secondary battery system 120.

The deterioration estimation control of the secondary battery 110 illustrated in FIG. 2 is started, for example, when the ignition of the vehicle is turned off (IGR-OFF) and the vehicle is stopped (the driving is finished). Even immediately after the ignition of the vehicle is turned on (IGR-ON), the deterioration estimation control of the secondary battery 110 can be executed as long as the system of the vehicle is activated.

### S201

The information acquisition unit 121 acquires the state of the battery cell 111 from the secondary battery 110. The state of the battery cell 111 is a voltage, a current, a temperature, and an internal pressure of the battery cell 111 detected by the voltage/current/temperature sensor 113 and the pressure sensor 114, respectively.

When the state of the battery cell 111 is acquired by the information acquisition unit 121, the process proceeds to S202.

### S202

The deterioration estimation unit 122 determines the relationship between the temperature T of the battery cell 111 of the secondary battery 110 and the first threshold value th1 and the second threshold value th2 set in advance. Here, the first threshold value th1 is set to any temperature in the first temperature range (for example, 0° C. to 10° C.). The first temperature range is a low temperature range in which the deterioration estimation method based on the internal resistance due to the discharge of the battery cell 111 is more accurate than the deterioration estimation method based on the internal pressure measured by the pressure measurement of the battery cell 111. The second threshold value th2 is set to any temperature (for example, 30° C. to 40° C.) in the second temperature range. The second temperature range is a high temperature range in which the deterioration estimation method based on the internal pressure measured by the pressure measurement of the battery cell 111 is more accurate than the deterioration estimation method based on the internal resistance due to the discharge of the battery cell 111.

When the deterioration estimation unit 122 determines that the temperature T of the battery cell 111 is equal to or lower than the first threshold value th1 (S202, T≤th1), the process proceeds to S203.
When the deterioration estimation unit 122 determines that the temperature T of the battery cell 111 is equal to or higher than the second threshold value th2 (S202, th2≤T), the process proceeds to S204.
When the deterioration estimation unit 122 determines that the temperature T of the battery cell 111 is higher than the first threshold value th1 and lower than the second threshold value th2 (S202, th1<T<th2), the process proceeds to S205.

### S203

The deterioration estimation unit 122 estimates the deterioration of the secondary battery 110 by using a deterioration estimation method based on the internal resistance due to the discharge of the battery cell 111, since the temperature T of the battery cell 111 is in the low temperature range (first estimation unit). The voltage and the current of the battery cell 111 acquired from the secondary battery 110 by the information acquisition unit 121 are used for the deterioration estimation. In the low temperature range, the accuracy of the deterioration estimation method based on internal resistance due to discharge of the battery cell 111 is higher than the accuracy of the deterioration estimation method based on internal pressure due to pressure measurement of the battery cell 111. Therefore, the deterioration estimation method based on the internal resistance due to discharge of the battery cell 111 is exclusively performed.

As a deterioration estimation method based on the internal resistance due to the discharge of the battery cell 111, a resistance value and a capacity value measured by a well-known resistance measurement method or a capacity measurement method are compared with initial values to calculate a deterioration rate of the secondary battery 110. The following expressions can be used for the calculation.

$$Resistance [ Ω ] = Section capacity [ Ah or F ] / Measuring current [ I ]$$

$$Capacity [ Ah or F ] = Battery - specific coefficient \times Section capacity [ Ah or F ]$$

$$Section capacity [ Ah or F ] = Measuring current [ I ] \times time [ t ] ( or a battery - specific coefficient \times ( V {1}^{2} - V {2}^{2} ) )$$

When the deterioration estimation unit 122 estimates the deterioration of the secondary battery 110 exclusively by using the deterioration estimation method based on the internal resistance due to the discharge of the battery cell 111, the process proceeds to S206.

### S204

The deterioration estimation unit 122 estimates the deterioration of the secondary battery 110 by using the deterioration estimation method based on the internal pressure of the battery cell 111 measured by the pressure measurement, since the temperature T of the battery cell 111 is in the high temperature range (second estimation unit). The internal pressure of the battery cell 111 acquired from the secondary battery 110 by the information acquisition unit 121 is used for the deterioration estimation. In the high temperature range, the accuracy of the deterioration estimation method based on internal pressure measured by pressure measurement of the battery cell 111 is higher than the accuracy of the deterioration estimation method based on internal resistance due to discharge of the battery cell 111. Therefore, the deterioration estimation method based on the internal pressure measured by pressure measurement of the battery cell 111 is exclusively performed. As a result, the performance estimation of the secondary battery 110 in the final stage of deterioration can be accurately performed, design for securing extra cell performance is not needed, and it is possible to reduce cost while ensuring quality.

As a deterioration estimation method based on the internal pressure of the battery cell 111 measured by the pressure measurement, a method of comparing the internal pressure of the battery cell 111 at the initial time at the same temperature with the internal pressure of the battery cell 111 at a certain point in time, and calculating the deterioration rate of the secondary battery 110 by multiplying the corresponding unique coefficient can be shown. The coefficients are created in advance as a map for control by the temperature and the state of charge (SOC) of the battery cell 111 and stored in an electronic control unit (ECU) or the like for use in calculations. Alternatively, since the internal pressure p shows a linear correlation in accordance with the state equation “pV=nRT” with respect to the temperature T, the equation may be used.

When the deterioration estimation unit 122 estimates the deterioration of the secondary battery 110 exclusively by using the deterioration estimation method based on the internal pressure measured by the pressure measurement of the battery cell 111, the process proceeds to S206.

### S205

The temperature T of the battery cell 111 is in a normal temperature range between a low temperature range and a high temperature range. Therefore, the deterioration estimation unit 122 estimates the deterioration of the secondary battery 110 by using both the deterioration estimation method based on the internal resistance due to the discharge of the battery cell 111 and the deterioration estimation method based on internal pressure measured by pressure measurement of the battery cell 111 (third estimation unit). The voltage, the current, and the internal pressure of the battery cell 111 acquired from the secondary battery 110 by the information acquisition unit 121 are used for the deterioration estimation. In the normal temperature range, the accuracy of the deterioration estimation method based on the internal resistance due to the discharge of the battery cell 111 is low, and thus the deterioration estimation method based on the internal pressure measured by the pressure measurement of the battery cell 111 is used in combination to ensure high accuracy. As a result, the performance estimation of the secondary battery 110 in the final stage of deterioration can be accurately performed, design for securing extra cell performance is not needed, and it is possible to reduce cost while ensuring quality.

In the normal temperature range, the absolute value of the resistance value is reduced in both the case of the deterioration estimation due to the discharge and the case of the deterioration estimation due to the pressure, and the difference in the absolute value between before the deterioration and after the deterioration is reduced. Therefore, considering the influence of an error of the sensor used for the measurement, it is expected that the accuracy is low with a single deterioration estimation, and thus both deterioration estimations are performed. Mathematical methods, such as a least squares method, a Kalman filter, and a Bayesian estimation, can be used in the deterioration estimation method that uses both the measurement results. Both measurement errors (particularly, deterioration estimation due to discharge) are not caused by random errors, but are caused by systematic errors, that is, bias. Therefore, the advantage of performing both the deterioration estimation for the case where the one deterioration estimation is simply performed multiple times and the deterioration estimation for the case where both the deterioration estimations are performed is that the bias unique to the one measurement can be offset by combining different types of measurements. For example, the measurement error by the voltage sensor includes temperature dependence of the sensor, influence by noise or electromagnetic interference, linearity error of the sensor, offset error, phase error, influence of impedance, magnetic hysteresis, and influence of wiring to other devices. The errors are more due to a bias than random.

When the deterioration estimation unit 122 estimates the deterioration of the secondary battery 110 by using both the deterioration estimation method based on the internal pressure due to the internal pressure measurement of the battery cell 111 and the deterioration estimation method based on the internal resistance due to the discharge of the battery cell 111, the process proceeds to S206.

### S206

The deterioration estimation unit 122 determines the deterioration rate estimated in any one of S203 to S205 described above as the deterioration rate of the secondary battery 110.

When the deterioration rate of the secondary battery 110 is determined by the deterioration estimation unit 122, the deterioration estimation control of the secondary battery 110 ends.

After the deterioration rate of the secondary battery 110 is determined in S206, the failure detection of the secondary battery 110 may be performed. As a result of the above-described operation, when the failure of the secondary battery 110 is not detected, the operation of the secondary battery system 120 may be stopped to set the secondary battery system 120 to the activation wait state (sleep state). On the other hand, when the failure of the secondary battery 110 is detected, the failure may be determined and a treatment such as turning on a diagnostic lamp light may be performed.

In a case where the battery resistance is measured using a short-time pulse discharge (0.1 sec to 0.5 sec) and the battery SOC is estimated based on the measurement result, the battery pressure correction value may be calculated from the battery SOC.

### Operation and Effects

As described above, the secondary battery system 120 according to the embodiment of the present disclosure, in accordance with the temperature T of the battery cell 111, estimates the deterioration of the secondary battery 110 based on the internal resistance when the temperature T is in the low temperature range, estimates the deterioration of the secondary battery 110 based on the internal pressure when the temperature T is in the high temperature range, and estimates the deterioration of the secondary battery 110 based on both the internal resistance and the internal pressure when the temperature T is in the normal temperature range.

With the deterioration estimation method, it is possible to improve the accuracy of the deterioration estimation of the secondary battery 110. Therefore, the performance estimation in the late stage of deterioration of the secondary battery 110 can be accurately performed, design for securing extra cell performance is not needed, and it is possible to reduce cost while ensuring quality.

Although the embodiment of the present disclosure has been described above, the present disclosure is not limited to the secondary battery system. The present disclosure can be regarded as a method executed by a secondary battery system including a processor and a memory, a program for executing the method, a computer-readable non-transitory storage medium storing the program, a vehicle mounting the secondary battery system, and the like.

The secondary battery system of the present disclosure can be used in a case where the deterioration of the secondary battery is to be estimated with high accuracy.

What is claimed is:

1. A secondary battery system that estimates deterioration of a secondary battery, the secondary battery system comprising:
an acquisition unit configured to acquire an internal resistance, an internal pressure, and a temperature of a battery cell;
a first estimation unit configured to estimate the deterioration of the secondary battery based on the internal resistance when the temperature is equal to or lower than a first threshold value;
a second estimation unit configured to estimate the deterioration of the secondary battery based on the internal pressure when the temperature is equal to or higher than a second threshold value; and
a third estimation unit configured to estimate the deterioration of the secondary battery based on both the internal resistance and the internal pressure when the temperature is higher than the first threshold value and lower than the second threshold value.

2. The secondary battery system according to claim 1, wherein the acquisition unit is configured to acquire the internal pressure by detecting a change in a cell internal pressure due to gas generated as the deterioration of the battery cell progresses.
